(19) United States
(12) Patent Application Publication
(10) Pub. No.: US 2025/0185441 A1
(43) Pub. Date: Jun. 5, 2025

(54) QUANTUM ELECTRON STORAGE DEVICE AND METHOD OF USE

(71) Applicant: John Felten, SR., Chapel Hill, NC (US)

(72) Inventor: John Felten, SR., Chapel Hill, NC (US)

(21) Appl. No.: 18/951,295

(22) Filed: Nov. 18, 2024

Related U.S. Application Data
(60) Provisional application No. 63/600,384, filed on Nov. 17, 2023.

(51) Int. Cl. H10K 10/10; H10K 85/30

(52) U.S. Cl. CPC H10K 10/10; H10K 85/311; H10K 85/371; H10K 85/381

(57) ABSTRACT

Quantum electron storage devices are provided. In some aspects, a device is provide with a working voltage of 50V or more, 90V or more, 100V or more, or from 90V to 150V. The device has an energy density of 300 Watt hours or more, 500 watt hours or more, or 1,000 watt hours or more per kilogram of quantum electron storage material at these working voltages. The device includes 1 or more layers of quantum electron storage material. A method of using the quantum electron storage devices includes a step of applying a working voltage of 50V or more, 90V or more, 100V or more, or from 90V to 150V to the device. The quantum electron storage devices described herein are particularly useful in laser weapons due to their high energy density and fast charge and discharge rates.

### CROSS-REFERENCE TO RELATED APPLICATIONS

This application claims priority to U.S. Provisional Patent Application No. 63/600,384 filed on Nov. 17, 2023, the content of which are incorporated herein by reference in their entirety.

### FIELD

The technology described herein generally relates to energy storage devices and methods of using the same, and more particularly quantum electron storage devices, which in some aspects have high energy storage density.

### BACKGROUND

Fossil fuels, such as gasoline have an extremely high energy density, producing about 2,000 watt-hours per kilogram. Thus, finding technology that can rival fossil fuels energy density has been a goal of those working in the field of energy storage.

Currently, lithium ion batteries have one of the highest energy densities, ranging from about 100 to 265 watt-hours per kilogram. Super capacitors have significantly lower energy densities, e.g., less than 10 watt-hours per kilogram. Working voltages for super capacitors and lithium ion batteries are typically less than 5 V. Thus, even today, fossil fuels have an energy density that is orders of magnitude larger than state-of-the-art energy storage devices.

Previous approaches to quantum electron storage devices have focused on improving the performance and efficiency of energy storage systems. These devices typically utilize various materials and configurations to store and release electrons for energy storage purposes. However, these approaches have faced challenges in achieving high working voltages and energy densities, which are crucial for maximizing the capacity and efficiency of the storage device.

In some prior art approaches, quantum electron storage devices have utilized conventional materials that have limited working voltage capabilities. These devices have struggled to achieve working voltages of 90V or more, which restricts their ability to store and deliver higher amounts of energy. Additionally, the energy density of these devices has been limited to below 300 watt hours per kilogram of quantum electron storage material, resulting in lower overall energy storage capacity.

Other previous approaches have attempted to enhance the working voltage and energy density of quantum electron storage devices by utilizing advanced materials. These materials, such as certain metal oxides or semiconductors, have shown promise in achieving higher working voltages and energy densities. However, these approaches have often been limited by challenges in material synthesis, device fabrication, and overall system integration, which have hindered their practical implementation.

Furthermore, some prior art quantum electron storage devices have focused on improving either the working voltage or the energy density, but not both simultaneously. These approaches have resulted in trade-offs between voltage and energy density, limiting the overall performance and efficiency of the storage device.

However, none of these approaches have provided a comprehensive solution that combines the features described in this disclosure. In contrast to conventional energy storage devices, and attempts to provide quantum electron storage devices, the present technology addresses the need for a quantum electron storage device that can achieve a working voltage of 90V or more and an energy density of 300 watt hours or more per kilogram of quantum electron storage material, thereby enabling high-capacity and efficient energy storage. Additionally, aspects of the technology described herein can further provide safety features, for instance the ability to extinguish itself or control catastrophic failure.

### SUMMARY

This summary is provided to introduce a selection of concepts in a simplified form that are further described below in the detailed description. This summary is not intended to identify key features or essential features of the claimed subject matter, nor is it intended to be used in isolation as an aid in determining the scope of the claimed subject matter.

Embodiments of the technology described herein are directed towards energy storage devices and methods of using the same, and more particularly quantum electron storage devices, which in some aspects have high energy storage density. In some aspects, for example, a quantum electron storage device can have an energy density greater than 300 watt-hours per kilogram (Wh/kg) is observed using a working voltage from 90 to 150V.

According to some aspects, a quantum electron storage devices described herein exhibits energy densities that exceed those of typical lithium ion batteries, that are orders of magnitude larger those of typical super capacitors, and that come closer to achieving the dream of parity with fossil fuels. Additionally, the quantum electron storage devices described herein have extremely fast charge and discharge rates, even exceeding those of super capacitors, in some instances. The high energy densities, coupled with fast charge/discharge rates, make these quantum electron storage devices uniquely suited for high power application, for example for powering laser weapons.

In one aspect, a quantum electron storage device comprising at least one layer of quantum electron storage material is described herein. In some embodiments, the device may have two or more layers of quantum electron storage material. In other embodiments, the device may have between three to five hundred layers of quantum electron storage material.

The device may have a working voltage of 90V or more, 100 V or more, or from 90V to 150V. The energy density of the device at this working voltage may be 300 watt hours or more per kilogram of quantum electron storage material, 500 watt hours or more per kilogram of quantum electron storage material, or 1,000 watt hours or more per kilogram of quantum electron storage material.

The quantum electron storage material, in some embodiments, comprises phthalocyanine that is non-aromatic according to Huckel's rule (4n+2 rule). For example, the quantum electron storage material may comprise blue copper phthalocyanine, zinc phthalocyanine, green copper phthalocyanine, or combinations thereof.

In some embodiments, the quantum electron storage material is provided on a metal foil. For example, it may be provided on a copper metal foil or aluminum metal foil.

In some embodiments, the quantum electron storage device is formed by providing a quantum electron storage material on a first metal foil, providing a quantum electron storage material on a second metal foil, and contacting the layer of quantum electron storage material on the first metal foil with the layer of quantum electron storage material on the second metal foil to form a junction, e.g., a semiconductor junction. The first and second foils may be copper foils. In some embodiments, the quantum electron storage material provided on the first metal foil and the quantum electron storage material provided on the second foil may both comprise blue copper phthalocyanine. The quantum electron storage material provided on the first and second metal foils may be the same or different materials.

In another aspect, a method of using the quantum electron storage devices described herein is described. The method may comprise a step of applying a working voltage to the device. For example, a voltage of 90V or more, 100V or more, or from 90V to 150V may be applied.

In some embodiments, a quantum electron storage device is provided comprising one or more storage layers and one or more junction layers. In some instances, a storage layer comprises a metal foil and a quantum electron storage material. In some instances, one or more junction layers comprise a first metal foil provided with a layer comprising a quantum electron storage material, and a second metal foil provided with a layer comprising a quantum electron storage material, wherein the first metal foil provided with a layer comprising a quantum electron storage material and the second metal foil provided with a layer comprising a quantum electron storage material are arranged so that the layers comprising a quantum electron storage material are in contact with one another and form a junction.

Additional objects, advantages, and novel features of the invention will be set forth in part in the description which follows, and in part will become apparent to those skilled in the art upon examination of the following, or can be learned by practice of the invention.

### BRIEF DESCRIPTION OF THE DRAWINGS

Many aspects of the present disclosure can be better understood with reference to the following drawings. The components in the drawings are not necessarily to scale, with emphasis instead being placed upon clearly illustrating the principles of the disclosure. Moreover, in the drawings, like reference numerals designate corresponding parts throughout the several views. In the drawings

FIG. 1 illustrates a metal foil provided with a layer of quantum electron storage material in accordance with some aspects of the technology described herein;

FIG. 2 illustrates an arrangement of two metal foils, each coated with a layer of quantum electron storage material, to form a junction, in accordance with some aspects of the technology described herein;

FIG. 3 illustrates an example quantum electron storage module, in accordance with some aspects of the technology described herein;

FIG. 4 illustrates an example quantum electron storage device, in accordance with some aspects of the technology described herein;

FIG. 5 illustrates an example quantum electron storage device and/or module, in accordance with some aspects of the technology described herein; and

FIG. 6 illustrates the performance of an example quantum electron storage device, in accordance with some aspects of the technology described herein.

### DETAILED DESCRIPTION

The subject matter of aspects of the present disclosure is described with specificity herein to meet statutory requirements. However, the description itself is not intended to limit the scope of this patent. Rather, the inventors have contemplated that the claimed subject matter might also be embodied in other ways, to include different steps or combinations of steps similar to the ones described in this document, in conjunction with other present or future technologies. Moreover, although the terms “step” and/or “block” can be used herein to connote different elements of methods employed, the terms should not be interpreted as implying any particular order among or between various steps disclosed herein unless and except when the order of individual steps is explicitly described.

Accordingly, embodiments described herein can be understood more readily by reference to the following detailed description, examples, and figures. Elements, apparatus, and methods described herein, however, are not limited to the specific embodiments presented in the detailed description, examples, and figures. It should be recognized that the exemplary embodiments herein are merely illustrative of the principles of the invention. Numerous modifications and adaptations will be readily apparent to those of skill in the art without departing from the scope of the invention.

In addition, all ranges disclosed herein are to be understood to encompass any and all subranges subsumed therein. For example, a stated range of “1.0 to 10.0” should be considered to include any and all subranges beginning with a minimum value of 1.0 or more and ending with a maximum value of 10.0 or less, e.g., 1.0 to 5.3, or 4.7 to 10.0, or 3.6 to 7.9.

All ranges disclosed herein are also to be considered to include the end points of the range, unless expressly stated otherwise. For example, a range of “between 5 and 10” or “5 to 10” or “5-10” should generally be considered to include the end points 5 and 10.

Further, when the phrase “up to” is used in connection with an amount or quantity; it is to be understood that the amount is at least a detectable amount or quantity. For example, a material present in an amount “up to” a specified amount can be present from a detectable amount and up to and including the specified amount.

Additionally, in any disclosed embodiment, the terms “substantially,” “approximately,” and “about” may be substituted with “within [a percentage] of” what is specified, where the percentage includes 0.1, 1, 5, and 10 percent.

Disjunctive language such as the phrase “at least one of X, Y, or Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

At a high level, aspects of the present technology are directed to quantum electric storage devices incorporating quantum electron storage materials. In some instances, a quantum electric storage device and/or module comprise one or more quantum electron storage material layers and one or more foil layers. In some instances, a quantum electron storage material layer and a foil layer combination refers to a quantum electron storage layer (QESL). In some aspects, a quantum electron storage device (QESD) or a quantum electron storage module (QESM) can comprise one or more storage layers (e.g. one or more QESLs). In some instances, a device can comprise one or more QESL, for example up to 10 storage layers, up to 20 storage layers, up to 50 storage layers, up to 100 storage layers, or more.

In some instances, a quantum electric storage device and/or module can comprise one or more junction layers. In some aspects, two or more quantum electron storage material layer and/or foil layer combinations can be stacked, for instance in series, and form one or more or a plurality of junctions. The junctions in some aspects are formed at the interface of the quantum electron storage material layer/quantum electron storage material layer of at least two opposing quantum electron storage layers.

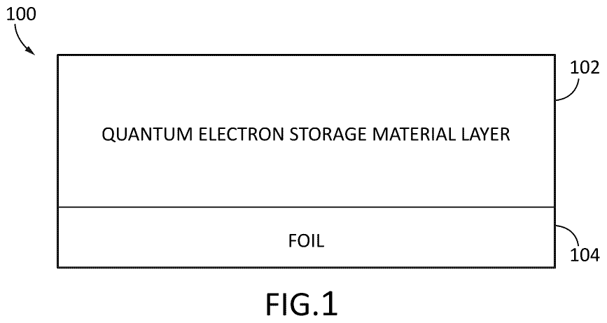

Referring to FIG. 1, an example quantum electron storage layer 100 is illustrated, in accordance with some embodiments of the present technology. Quantum electron storage layer (or storage layer) 100 can comprise a quantum electron storage material 102 (e.g. comprising a phthalocyanine) provided or disposed on a foil 104, for example a copper (Cu) foil or an aluminum (Al) foil. As will be appreciated, other foils not inconsistent with the objectives of the present disclosure may also be used. In some aspects, a quantum electron storage material can comprise a phthalocyanine, a combination of phthalocyanines, and one or more additional components. Any additional components not inconsistent with the present disclosure may be used, for example additional components can comprises one or more alcohols, resins, viscosity modifying agents or plasticizers, and/or conduction materials.

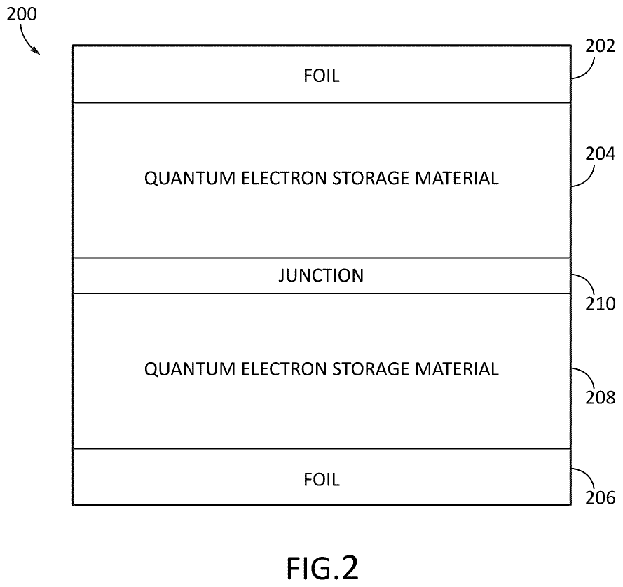

Turning now to FIG. 2, an example junction layer or quantum electron junction layer 200 is illustrated, in accordance with some embodiments of the present technology. Quantum electron junction layer (or junction layer) comprises at least two foils 202, 204 and at least two opposing quantum electron storage material layers 204, 208. In some aspects, a junction (or junction layer) can comprise a first metal foil provided with a layer comprising a quantum electron storage material, and a second metal foil provided with a layer comprising a quantum electron storage material, wherein the first metal foil provided with a layer comprising a quantum electron storage material and the second metal foil provided with a layer comprising a quantum electron storage material are arranged so that the layers comprising a quantum electron storage material are in contact with one another, forming a junction 210. In some aspects, it will be appreciated that junction 210 is formed at the interface of two quantum electron storage material layers. In some aspects, the junction layer can be electron doped.

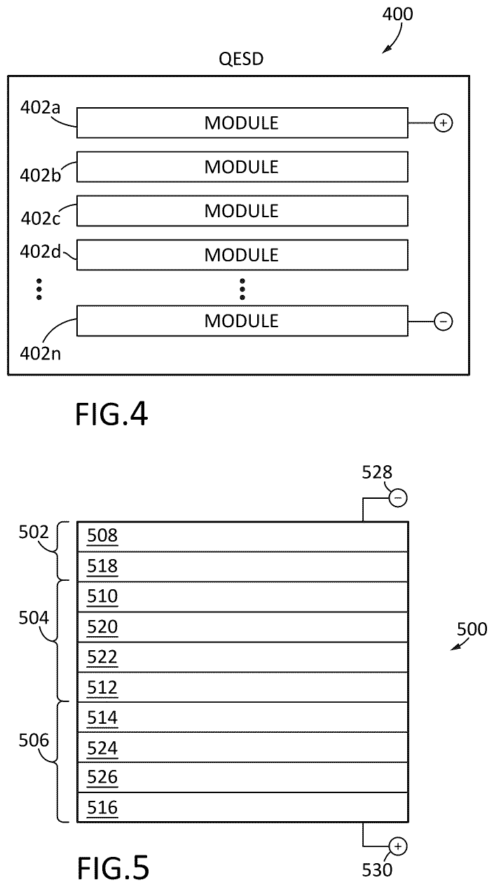

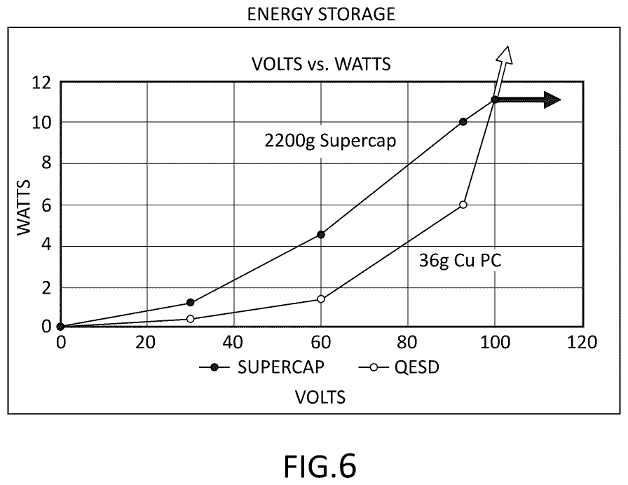

In some embodiments, a quantum electron storage device and/or module comprises at least one storage layer and at least one junction layer. In some embodiments a quantum electron storage device comprises at least one storage layer and at least two, or at least three junction layers. Turning to FIG. 4, an example of a storage device 400 is illustrated, in accordance with some aspects of the present technology. Storage device 400 is shown comprising one storage layer 402, and two junction layers 404 and 406. As will be appreciated, any number of storage layers and/or junction layers may be implemented and in any order, not inconsistent with the objectives of the present technology. For example, another storage layer can be formed above storage layer 402, or for instance, between junction layers 404 and 406. In some aspects, another junction layer can be formed above storage layer 402 or below junction layer 406 such that the device and/or module 400 comprises one or more storage layers 402, 402n, and one or more junction layers, e.g. two or more, three or more, junction layers. As will be appreciated, and further described herein, any number of junction layers and/or storage layers may be utilized or configured to achieve the operating voltage and/or storage capacity specifications described herein. In some aspects, device 400 comprises foil layers (e.g. Cu, Al) 408, 410, 412, 414, 416. In some further aspects, device 400 comprises storage material layers (e.g. quantum electron storage material, phthalocyanine, among others) 418, 420, 422, 424, 426. In some aspects, storage layer 402 can be connected to, or in operable communication with, a negative electrode 428 and one of storage layers 404, 406 can be connected to, or in operable communication with, a positive electrode. In accordance with some aspects of the technology, there is little or no voltage drop (i.e. little to no resistance) created across one or more storage layers (e.g. storage layer 402), and the junction layer(s) (e.g. junction layers 404, 406) can be configured to create high resistance, for instance between a storage layer and a positive electrode. In some instances, each junction layer can be configured to provide or enable up to a 50 V drop across the junction. In some instances, a storage layer can have an energy density of about up to 100 Wh/kg per kilogram of storage material. Referring briefly to FIG. 5, the performance of a quantum electron storage device in accordance with some aspects of the present invention is shown comparative to a supercapacitor is provided. In some example embodiments, as shown, a device in accordance with some embodiments of the present technology displays higher power output and/or better storage capacity, for instance particularly at higher operating voltages.

In some embodiments, one or more storage devices and/or modules (e.g. device/module 400) can be connected to another device/module, for example in any configuration not inconsistent with the objectives of the present technology, for example, devices/modules can be connected in series, parallel, or a combination thereof.

In some aspects, a quantum electron storage device has a working voltage of 50V or more, 60V or more, 70V or more, 80V or more, 90V or more, 100V or more, 110V or more, 120V or more, 130V or more, 140V or more, or 150V or more. In some embodiments, the device has a working voltage of 90V or more, 100V or more, 110V or more, 120V or more, 130V or more, 140V or more, or 150 V or more. In some embodiments, the working voltage may be from 90V to 150V. Working voltage has an art-recognized meaning, and typically describes the standard operating voltage of a device. In some embodiments, a quantum electron storage device has a working voltage of 90V or more or 100V or more. In some other embodiments, the working voltage may be from 50V to 150V, for example 100V to 150V. Notably, the working voltage of these devices are orders of magnitude greater than the working voltage for lithium ion batteries and super capacitors, which typically have working voltages less than 5V.

In some aspects, the energy density of a quantum electron storage device described herein is high. In some instances, the energy density of a quantum electron storage device at a working voltage of 50V or more, is 300 watt hours or more per kg of quantum electron storage material. In some embodiments, the energy density is 310 watt hours or more per kg of quantum electron storage material, 320 watt hours or more per kg of quantum electron storage material, 330 watt hours or more per kg of quantum electron storage material, 340 watt hours or more per kg of quantum electron storage material, 350 watt hours or more per kg of quantum electron storage material, 360 watt hours or more per kg of quantum electron storage material, 370 watt hours or more per kg of quantum electron storage material, 380 watt hours or more per kg of quantum electron storage material, 390 watt hours or more per kg of quantum electron storage material, 400 watt hours or more per kg of quantum electron storage material, 410 watt hours or more per kg of quantum electron storage material, 420 watt hours or more per kg of quantum electron storage material, 430 watt hours or more per kg of quantum electron storage material, 440 watt hours or more per kg of quantum electron storage material, 450 watt hours or more per kg of quantum electron storage material, 460 watt hours or more per kg of quantum electron storage material, 470 watt hours or more per kg of quantum electron storage material, 480 watt hours or more per kg of quantum electron storage material, 490 watt hours or more per kg of quantum electron storage material, 500 watt hours or more per kg of quantum electron storage material, 550 watt hours or more per kg of quantum electron storage material, 600 watt hours or more per kg of quantum electron storage material, 650 watt hours or more per kg of quantum electron storage material, 700 watt hours or more per kg of quantum electron storage material, 750 watt hours or more per kg of quantum electron storage material, 800 watt hours or more per kg of quantum electron storage material, 850 watt hours or more per kg of quantum electron storage material, 900 watt hours or more per kg of quantum electron storage material, 950 watt hours or more per kg of quantum electron storage material, or 1,000 watt hours or more per kg of quantum electron storage material. These energy densities exceed those of typical lithium ion batteries (e.g., about 100 to 265 watt-hours per kilogram), are orders of magnitude larger those of typical super capacitors (e.g., e.g., less than 10 watt-hours per kilogram), and are closer to achieving close to parity with fossil fuels energy densities (e.g., about 2,000 watt-hours per kilogram).

In some embodiments, the device comprises, consists of, or consists essentially of one or more, two or more, three or more, four or more, five or more, six or more, seven or more, eight or more, nine or more, ten or more layers, eleven or more later, twelve or more layers, thirteen or more layer, fourteen or more layers, fifteen or more layers, sixteen or more layers, seventeen or more layers, eighteen or more layers, nineteen or more layers, or twenty or more, thirty or more, forty or more, fifty or more, sixty or more, seventy or more, eighty or more, ninety or more, one hundred or more, two hundred or more, three hundred or more, four hundred or more, or five hundred or more layers of quantum electron storage material. In devices having two or more layers of quantum electron storage material, the layers may have the same or different quantum electron storage material. The layers of quantum electron storage material may comprise, consist of, or consist essentially of quantum electron storage material. In some aspects, the layers comprise a quantum electron storage material layer on a foil or substrate layer.

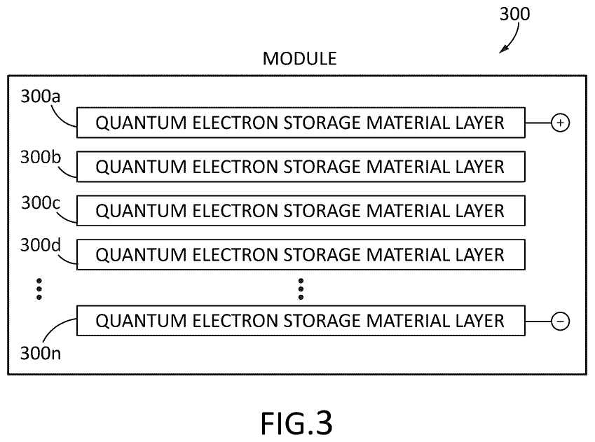

In some embodiments, the device is formed from two more, three or more, four or more, five or more, six or more, seven or more, eight or more, nine or more, or ten or more modules. Referring to FIG. 4, a device (QESD) 400, can comprise one or more modules 402a, 402b, 402c, 402d, 402n. Each module may comprise one or more, two or more, ten or more, twenty or more, thirty or more, forty or more, fifty or more, sixty or more, seventy or more, eighty or more, ninety or more, or one hundred or more layers of quantum electron storage material. Referring to FIG. 3, a module (QESM) 300 can comprise one or more storage material layers 302a, 302b, 302c, 302d, 302n. In some embodiments, each layer can have a given energy density, e.g., 10 watt hours per layer, and the energy density of the module may be calculated by multiplying the energy density per layer, e.g., 10 watt hours per layer, times the number of layers. Energy density of a layer may be increased, for example, by increasing the coating density of the layer so that more grams of quantum electron storage material are included in the layer. As shown in FIG. 4, a QESD may be made up of one or more modules. Energy density of the QESD may be calculated by multiplying the energy density of the module times the number of modules in the QESD.

The quantum electron storage material of each layer may comprise, consist of, or consist essentially of a single acceptable quantum electron storage material or mixtures of acceptable quantum electron storage materials. The quantum electron storage material is not so limited.

In some embodiments, the quantum electron storage material may comprise, consist of, or consist essentially of a phthalocyanine dye that is non-aromatic according to Huckel's rule (i.e., the 4n+2 rule). For example, phthalocyanines with 4, 8, 12, 15, or 17 pi electrons would be non-aromatic according to Huckel's rule. The phthalocyanine molecule is a ring system that contains 15 delocalized electrons. A copper phthalocyanine molecule adds two electrons to produce an anion structure containing 1π electrons, i.e., one unpaired electron. Huckel's rule (or the “4n+2” rule) indicates that systems with 2, 6, 10, 14, 18 . . . pi electrons are favored over other numbers. Thus, the addition of a single electron brings the cu phthalocyanine molecule to a favored number, i.e., 18 pi electrons. Without wishing to be bound by any particular theory, it is believed that the addition of an electron is what enables the exceptionally high energy storage density observed herein to be achieved.

Different types of phthalocyanine complexes, e.g., copper, zinc, nickel, or iron complexes with phthalocyanine) have different energy levels in their excited state, and thus will have significantly different working voltages. For example, zinc phthalocyanine will operate at voltages below 100 Volts or below 90 Volts. Unfortunately, zinc phthalocyanine is expensive. Green copper phthalocyanine has a working voltage over 100 volts. Blue copper phthalocyanine has a working voltage in the range of 100 to 150 volts. Use of the proper working voltage is important for the success of this invention. The working voltage of the device must match the working voltage of the quantum electron storage material. The system is a semi-conductor based system that uses a junction to prevent charge from escaping. Instead of polarization (as in a capacitive system) we are using a system that operates by storing energy in excited states at high voltage.

In some embodiments, the quantum electron storage material may comprise, consist of, or consist essentially of blue copper phthalocyanine, zinc phthalocyanine, green copper phthalocyanine, or combinations thereof.

In some other embodiments, the quantum electron storage materials may have one or both of the following properties: a band gap less than 6 eV, less than 4 eV; and a half-life for an excited state transition that is 5 seconds or less, 4 seconds or less, 3 seconds or less, 2 seconds or less, or 1 second or less resulting in exceedingly fast discharge times and low internal resistance.

In some embodiments, the layers of quantum electron storage material may comprise, consist of, or consist essentially of quantum electron storage material and a binder. The binder is not so limited, but in some embodiments, an organic binder is used. In some embodiments, binder is present in low amounts such as one percent or less or two percent or less of solids volume in the layer of quantum electron storage material. In some embodiments, the layers of quantum electron storage material do not comprise any binder.

The thickness of the layers of quantum electron storage material are not so limited, and may be in a range from 10 to 20 microns, 25 to 250 microns, from 50 to 250 microns, from 75 to 250 microns, from 100 to 250 microns, from 125 to 250 microns, from 150 to 250 microns, from 175 to 250 microns, from 200 to 250 microns, or from 225 to 250 microns. In some instances, the thickness of the layers of quantum electron storage material is less than 10 microns, or less than 8 microns.

The coating density of the layer or layers of quantum electron storage material are not so limited, and may be from 10 gsm to 100 gsm, from 20 gsm to 100 gsm, from 30 gsm to 100 gsm, from 40 gsm to 100 gsm, from 50 gsm to 100 gsm, from 60 gsm to 100 gsm, from 70 gsm to 100 gsm, from 80 gsm to 100 gsm, or from 90 gsm to 100 gsm.

In some embodiments, the layer or layers of quantum electron storage material are provided on a substrate. For example, in some embodiments, the layer or layers of quantum electron storage material are provided on a metal (e.g., copper, aluminum) foil. Providing the quantum electron storage material (e.g., a material comprising blue copper phthalocyanine, green copper phthalocyanine, or another phthalocyanine) on a copper foil is an improvement over providing ink on a paper substrate to form an ink-soaked paper as a junction material. For example, a much lower leakage is observed. For example, leakage is found to be undetectable (below 50 microamps) at 60V, or in some instances a low or undetectable leakage at 100V. In certain embodiments, two or more quantum electron storage layers can be configured such that increased working voltage leads to a lower or decreased leakage.

In some aspects, multiple junctions can be used to achieve a higher breakdown voltage (e.g., above 50V) which in some cases is needed for use of the higher working voltages described herein. For example, two or more, three or more or four or more junctions may be used. In some embodiments, only three or four junction layers provide the necessary breakdown resistance to achieve storage in excited states, greatly reducing the device's weight. In some aspects, the thickness of the foil may be from 5 to 20 microns. In some instances, the foil is from about 8 to about 10 microns. In some aspects, the number of junctions in a device, module, and/or series of layers can be configured such that the drop per junction is 50V or less.

In some embodiments, junctions may be formed by providing a quantum electron storage material on a first foil, providing a quantum electron storage material on a second foil, and arranging the quantum electron storage material on the first foil and the quantum electron storage material on the second foil so that they are in contact with one another. In some embodiments additional junctions may be formed through the use of providing a quantum electron storage material on a third foil, providing a quantum electron storage material on a fourth foil, and arranging the quantum electron storage material on the third foil and the quantum electron storage material on the fourth foil so that they are in contact with one another. In some embodiments additional junctions may be formed through the use of providing a quantum electron storage material on an nth foil, providing a quantum electron storage material on a nth+1 foil, and arranging the quantum electron storage material on the nth foil and the quantum electron storage material on the nth+1 foil so that they are in contact with one another. As will be appreciated this can form a stack of quantum electron storage layers (with two layers configured to form junction layer). Further, these pairs of junction layers (or any number of junction layers) may be stacked in series, such that the third and/or fourth foil is in contact with the first and/or second foil. Any number of additional storage layers (e.g. foil/material) or pairs of layers, i.e. junction layers (e.g. foil/material/material/foil) may further be implemented or included. For instance, 10 or more layers, 30 or more layers, 50 or more layers, 80 or more layers, 100 or more layers, 200 or more layers. The number of layers is not so limited. In one example a stack or series of junction layers can be provided with any number of junction layers (e.g. electron doped junctions) formed, for instance three junctions may be provided (QESM also referred to herein as material) for one or more storage layers (e.g. quantum electron storage layers. In some aspects, sets of layers, or a series of layers of any combination of storage layers and junctions layers can also be referred to as a stack. In some aspects it will be appreciated that the quantum electron storage material utilized in the junction layers can be the same or different materials.

In some embodiments, a device comprises one or more or a plurality of storage layers (e.g. foil layer with quantum electron storage material on it) stacked in series. The storage layers are terminated with one or more junction layers, comprised of two storage layers disposed face to face with the phthalocyanine coating layers in intimate contact with each other. In the storage layers the phthalocyanine layers are in intimate contact with the neighboring coper foil. Since the phthalocyanine layer is semiconductor in nature, it cannot form a semiconductor junction at the interface between phthalocyanine and copper (or aluminum) foil, but in the junction layer on layer of phthalocyanine is doped with the electrons used to charge the device, and a high resistance of up to ten megohms is generated at the point of contact between the two phthalocyanine layers. The breakdown voltage is about 50 volts, and the junction layers are stackable for multiples of 50 volts per layer to achieve higher working voltages. The junction prevents the loss of charge from the storage layer through the opposite electrode. Since discharging the storage layers causes voltage drop at the point of discharge, a semiconductor junction will form at the point of discharge, the middle of the phthalocyanine section of the storage layers. In some aspects, devices described herein can be configured to achieve discharge rate without problems of 150 Watt-hours from a device with only 9 grams of phthalocyanine, in devices with more than about 35 Volt working voltage. Similarly, at higher voltages one can charge the device with no observable voltage drop at high current (one ampere in a 9 gram device). In some instances, a device described herein can have a minimum working voltage of about 30 Volts.

In some embodiments, the use of multiple layers of quantum electron storage material and the formation of multiple junctions significantly reduces device weight and improves charge/discharge rates. The device can use as many has a hundred layers in parallel connected through a series of three or four junction layers to obtain a massively parallel device.

In some embodiments, the quantum electron storage devices described herein are solid-state devices. Solid-state devices, as understood by those skilled in the art, do not contain liquid electrolyte. In contrast, lithium-ion batteries typically use liquid electrolytes, which may not be environmentally friendly. Additionally, aspects of the technology described herein can further provide safety features over conventional batteries, for instance the ability to extinguish itself or control catastrophic failure.

Another aspect described herein is a method of using the quantum electron storage devices described herein. The method may comprise, consist of, or consist essentially of a step of applying a working voltage to a quantum electron storage device. The working voltage may be 50V or more, 60V or more, 70V or more, 80V or more, 90V or more, 100V or more, 110V or more, 120V or more, 130V or more, 140V or more, or 150V or more. In some embodiments, the working voltage may be 100V or more, or from 100V to 150V.

In some embodiments, a device and/or module can comprise two or more layers comprising a quantum electron storage material, for instance, a two or more storage layers each comprising a foil and a quantum electron storage material provided thereon. In some embodiments, the quantum electron storage material comprises a phthalocyanine that is non-aromatic. In some embodiments, a device or module comprises a storage layer and a junction layer. In some embodiments, a device and/or module can comprise at least another storage layer and/or at least another junction layer.

Another aspect described herein is a laser weapon comprising and powered by a quantum electron storage device as described herein. A laser weapon is a type of directed-energy weapon that uses lasers to inflict damage. Laser weapons may be used for defensive or offensive purposes. For example, they include laser-based missile systems and laser-based air defense systems.

### EXAMPLES

The following examples are provided to illustrate various aspects of the technology described herein and are not intended to be limiting of the various aspects and features described herein. In these examples, quantum electron storage devices as described herein are prepared and analyzed.

### Example 1a (a QESD w/Blue Copper Phthalocyanine)

Initially, the quantum electron storage material is formed. To achieve this, a slurry having a formulation as shown in Table 1 is formed:

TABLE 1

| Component | Amount | |
|---|---|---|
| 1. Blue Cu Phthalocyanine | 80 | grams |
| 2. acrylic resin powder | 50 | grams |
| 3. Isopropyl Alcohol | 200 | grams |
| 4. 3 micron copper powder | 133 | grams |
| 5. dioctyl phthalate | 18 | grams |
| 6. isopropyl alcohol | 191 | grams |

The above components were mixed thoroughly, and then blended with a handheld high-speed blender until an acceptable Hegman grind gauge measurement was obtained.

Next, foils are coated to create foils coated with quantum electron storage material. An example coated foil is shown in FIG. 1. To do this, copper foil (having a thickness under 20 microns) was laid down on a glass plate. About 60-80 ml of slurry was poured in a puddle at the end of the foil to be coated of about 0.2 inch thickness, with isopropyl alcohol added between cu foil and the glass plate to anchor the foil smoothly over the glass. The foil dimensions are 10×48 inches long. A Mayer bar with 0.8 mil groove and resting on a layer of duct tape about 2 mils thick was used to cast a layer about 5 mils thick on the foil. The casting was dried at room temperature and the foil dried in air hanging vertically overnight.

Next, the QESD is assembled. The coated sides of two foils coated with quantum electron storage material were pressed together in contact with each other to form a junction layer including a junction, e.g., a semiconductor junction. FIG. 2, which shows these junction layers including a junction. The junction, e.g., semi-conductor junction is roughly at the plane where the two layers of quantum electron storage material meet and touch.

As discussed herein, a sufficient number of junction layers are necessary to allow for use of higher working voltages.

One or more foils coated with quantum electron storage material are then added to the top of the junction layers, with the side coated with quantum electron storage material being pressed against the foil (bare copper side) of the previous layer. A sufficient number of foils coated with quantum electron storage material were added (about 9 grams of material per layer) to hold the desired charge amount, about 180 coulombs per gram of quantum electron storage material (blue Cu phthalocyanine in this example).

Example 1b (another QESD with blue copper phthalocyanine): This QESD is like that formed in Example 1a except that ink soaked paper was used instead of the coated foils. Ink soaked papers were formed by applying the slurry to a paper instead of a foil. The testing on coated soaked paper performed less than the coated foils in example 1a.

Example 2 (a QESD) with zinc phthalocyanine): This QESD is like that formed in Example 1a, except zinc phthalocyanine is used instead of blue copper phthalocyanine.

Example 3 (a QESD with green copper phthalocyanine): This QESD is like that formed in Example 1a, except green copper phthalocyanine is used instead of blue copper phthalocyanine.

Charge/Discharge Test Results and Analysis: Initial testing of zinc phthalocyanine performance gave significant storage at 16 V, about 1.33 W/h per layer. By way of contrast, green copper phthalocyanine could store much less power, about 05. w/layer at 32V, or about a projected 0.125 W/h at 16 Volts. However, the expense of zinc phthalocyanine prompted a search for other candidates. Blue copper phthalocyanine was also identified as a good candidate.

Testing (shown in Table 2 below) was conducted to measure aspects of example devices. A 30V test cycle yielded about 0.125 Watt/hour for 9-gram layer, i.e., about 14 watt hours per kilogram of material, impractically low for a super capacitor replacement, let alone fossil fuel replacement. A typical super capacitor will have an energy density of about 9 watt hours per kilogram. Gasoline has an extremely high energy density, producing about 2,000 watt-hours per kilogram.

If the device were a capacitor, only about 14 watt hours per kilogram of phthalocyanine would be expected at 30V or a projected 155 watt hours per kilogram at 100V if the device were a capacitor. Success depended on the device not behaving like a capacitor.

Testing at lower and higher voltages were conducted using the QESDs described in Example 1a. These results are shown in Table 2 below:

TABLE 2

| Charge | | Watt hours per | Watt hours per Kg of |
|---|---|---|---|
| Voltage | Layers | layer | blue Cu Phthalocyanine |
| 30 | 2 in parallel | 0.125 | 14 |
| 60 | 2 series, i@Vₘₐₓ | 1.5 | 165 |
| 92 | 2 series, i@Vₘₐₓ | 4 | ~500 |
| 99 | 2 series, i@Vₘₐₓ | 9-10 | ~1000-1100 |

The 99V results were replicated to reduce the chance of erroneous readings. It is clear that these QESDs are not capacitors based on their behavior. The series arrangement at 60V would only produce 0.125 watt hours per layer of blue copper phthalocyanine at 60V if these devices were capacitors.

Theoretical charge and energy storage is compared with Super capacitors and Li ion batteries. According to aspects of the present technology, a device can comprise a mole of copper phthalocyanine that, at full charge, assuming one electron per molecule, can store about 175,000 Coulombs at about 125V working voltage, or about 6250 Watt/hours theoretical. A 1 Kg super capacitor, by way of contrast, can only store about 9200 Coulombs at 2.7V, or about 9 Watt/hours per Kg. Lithium ion battery can hold 220,000 Coulombs of charge, but only at about 4V, or about 250 Watt/hrs.

Many different arrangements of the various components and/or steps depicted and described, as well as those not shown, are possible without departing from the scope of the claims below. Embodiments of the present technology have been described with the intent to be illustrative rather than restrictive. Alternative embodiments will become apparent from reference to this disclosure. Alternative means of implementing the aforementioned can be completed without departing from the scope of the claims below. Certain features and subcombinations are of utility and can be employed without reference to other features and subcombinations and are contemplated within the scope of the claims.

1. A quantum electron storage device comprising:
a storage layer, the storage layer comprising a metal foil and a quantum electron storage material; and
a junction layer, the junction layer comprising:
a first metal foil provided with a layer comprising a quantum electron storage material; and
a second metal foil provided with a layer comprising a quantum electron storage material,
wherein the first metal foil provided with a layer comprising a quantum electron storage material and the second metal foil provided with a layer comprising a quantum electron storage material are arranged so that the layers comprising a quantum electron storage material are in contact with one another and form a junction, and
wherein the device has a working voltage 90V or more and an energy density of 300 watt hours or more per kilogram of quantum electron storage material.

2. The device of claim 1, wherein the energy density is 500 watt hours or more per kilogram of quantum electron storage material.

3. The device of claim 1, wherein the energy density is 1,000 watt hours or more per kilogram of quantum electron storage material.

4. The device of claim 1, wherein the working voltage is 100V or more.

5. The device of claim 1, wherein the working voltage is from 90V to 150V.

6. The device of claim 1, comprising two or more layers comprising a quantum electron storage material.

7. The device of claim 1, comprising three to five hundred layers comprising a quantum electron storage material.

8. The device of claim 1, wherein the quantum electron storage material comprises a phthalocyanine that is non-aromatic.

9. The device of claim 8, wherein the electron storage material comprises at least one of blue copper phthalocyanine and/or green copper phthalocyanine.

10. The device of claim 8, wherein the electron storage material comprises zinc phthalocyanine.

11. The device of claim 1, further comprising at least one of another storage layer, the another storage layer comprising a metal foil and a quantum electron storage material.

12. The device of claim 1, wherein the metal foil is at least one of an aluminum foil and/or a copper foil.

13. The device of claim 1, further comprising at least one of another junction layer.

14. The device of claim 1, comprising:
at least a second junction layer, the second junction layer comprising:
a third metal foil provided with a layer comprising a quantum electron storage material; and
a fourth metal foil provided with a layer comprising a quantum electron storage material, wherein the third metal foil provided with a layer comprising a quantum electron storage material and the fourth metal foil provided with a layer comprising a quantum electron storage material are arranged so that the layers comprising a quantum electron storage material are in contact with one another and form a junction, and one of the third metal foil or the fourth metal foil is in contact with either the first metal foil or the second metal foil.

15. The device of claim 14, wherein the first and second metal foils are copper foils.

16. The device of claim 14, wherein the quantum electron storage material provided on the first metal foil and the quantum electron storage material provided on the second foil both comprise blue copper phthalocyanine.

17. The device of claim 14, wherein the quantum electron storage material provided on the first metal foil and the quantum electron storage material provided on the second foil are the same or different materials.

18. A method comprising, applying a voltage of 90V or more to the device of claim 1.

19. The method of claim 18 comprising applying a voltage of 100V or more to the device of claim 1.

20. The method of claim 18 comprising applying a voltage of 90V to 150V to the device of claim 1.
